(19) United States
(12) Patent Application Publication
(10) Pub. No.: US 2026/0111618 A1
(43) Pub. Date: Apr. 23, 2026

(54) SYSTEM

(71) Applicant: SoftBank Group Corp., Tokyo (JP)

(72) Inventor: Hiroki SUGAWARA, Tokyo (JP)

(21) Appl. No.: 19/353,199

(22) Filed: Oct. 8, 2025

(30) Foreign Application Priority Data
Oct. 18, 2024 (JP) 2024-183674

(51) Int. Cl. G06F 30/13; G06Q 50/26

(52) U.S. Cl. CPC G06F 30/13; G06Q 50/265

(57) ABSTRACT

The system according to the embodiment includes an acquisition unit, a design unit, and a verification unit. The acquisition unit acquires the latest policy. The design unit automatically performs design based on the policy acquired by the acquisition unit. The verification unit verifies the design generated by the design unit.

### CROSS-REFERENCE TO RELATED APPLICATION

The present application claims priority to and incorporates by reference the entire contents of Japanese Patent Application No. 2024-183674 filed in Japan on October 18, 2024.

### BACKGROUND OF THE INVENTION

### 1. Field of the Invention

The technology of this disclosure relates to a system.

### 2. Description of the Related Art

Japanese Patent Application Laid-open No. 2022-180282 discloses a persona chatbot control method executed by at least one processor, including: receiving a user utterance, adding the user utterance to a prompt containing instructions related to the character of the chatbot, encoding the prompt, inputting the encoded prompt into a language model, and generating a chatbot utterance in response to the user utterance.

In conventional technology, there has been a problem in that design based on the latest policies is performed manually, resulting in poor efficiency and a high likelihood of errors.

### SUMMARY OF THE INVENTION

The system according to the embodiment includes an acquisition unit, a design unit, and a verification unit. The acquisition unit acquires the latest policy. The design unit automatically performs design based on the policy acquired by the acquisition unit. The verification unit verifies the design generated by the design unit.

### BRIEF DESCRIPTION OF THE DRAWINGS

FIG. 1 is a conceptual diagram showing an example configuration of a data processing system according to the first embodiment;

FIG. 2 is a conceptual diagram showing an example of main functions of a data processing device and a smart device according to the first embodiment;

FIG. 3 is a conceptual diagram showing an example configuration of a data processing system according to the second embodiment;

FIG. 4 is a conceptual diagram showing an example of main functions of a data processing device and smart glasses according to the second embodiment;

FIG. 5 is a conceptual diagram showing an example configuration of a data processing system according to the third embodiment;

FIG. 6 is a conceptual diagram showing an example of main functions of a data processing device and a headset-type terminal according to the third embodiment;

FIG. 7 is a conceptual diagram showing an example configuration of a data processing system according to the fourth embodiment;

FIG. 8 is a conceptual diagram showing an example of main functions of a data processing device and a robot according to the fourth embodiment;

FIG. 9 shows an emotion map where multiple emotions are mapped; and

FIG. 10 shows an emotion map where multiple emotions are mapped.

### DETAILED DESCRIPTION OF THE PREFERRED EMBODIMENTS

Hereinafter, an example of an embodiment of the system related to the technology disclosed herein will be described with reference to the attached drawings.

First, the terminology used in the following description will be explained.

In the following embodiments, a processor with a sign (hereinafter simply referred to as "processor") may be a single computing device or a combination of multiple computing devices. The processor may be a single type of computing device or a combination of multiple types of computing devices. Examples of computing devices include a CPU (Central Processing Unit), GPU (Graphics Processing Unit), GPGPU (General-Purpose computing on Graphics Processing Units), APU (Accelerated Processing Unit), or TPU (Tensor Processing Unit), among others.

In the following embodiments, a RAM (Random Access Memory) with a sign is a memory where information is temporarily stored and used as a work memory by the processor.

In the following embodiments, a storage with a sign is one or more non-volatile storage devices for storing various programs and parameters. Examples of non-volatile storage devices include flash memory (SSD (Solid State Drive)), magnetic disks (e.g., hard disks), or magnetic tapes, among others.

In the following embodiments, a communication I/F (Interface) with a sign is an interface including a communication processor and an antenna, among others. The communication I/F manages communication between multiple computers. Examples of communication standards applicable to the communication I/F include wireless communication standards such as 5G (5th Generation Mobile Communication System), Wi-Fi (registered trademark), or Bluetooth (registered trademark), among others.

In the following embodiments, "A and/or B" means "at least one of A and B." In other words, "A and/or B" means it may be only A, only B, or a combination of A and B. Moreover, when expressing three or more items connected by "and/or," the same concept as "A and/or B" applies.

### First Embodiment

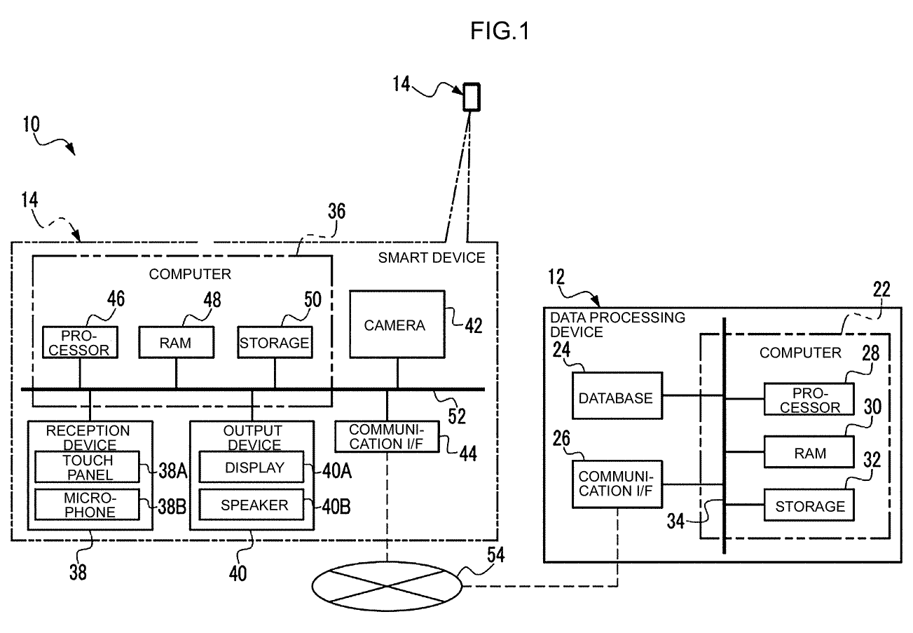

FIG. 1 shows an example configuration of a data processing system 10 according to the first embodiment.

As shown in FIG. 1, the data processing system 10 includes a data processing device 12 and a smart device 14. An example of the data processing device 12 is a server.

The data processing device 12 includes a computer 22, a database 24, and a communication I/F 26. The computer 22 includes a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The smart device 14 includes a computer 36, a reception device 38, an output device 40, a camera 42, and a communication I/F 44. The computer 36 includes a processor 46, RAM 48, and storage 50. The processor 46, RAM 48, and storage 50 are connected to a bus 52. The reception device 38, output device 40, and camera 42 are also connected to the bus 52.

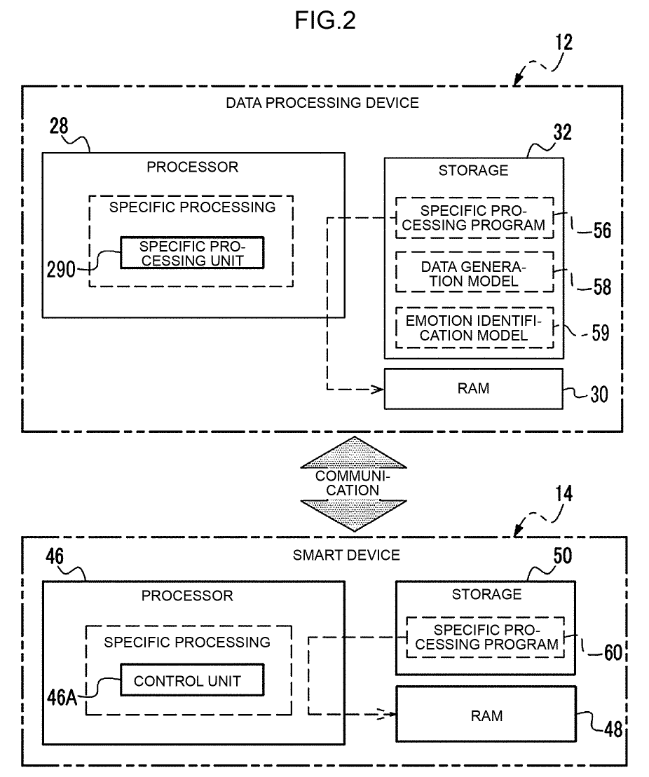

The reception device 38 includes a touch panel 38A and a microphone 38B, among others, and accepts user input. The touch panel 38A accepts user input by detecting contact from an indicating object (e.g., a pen or finger). The microphone 38B accepts user input by detecting the user's voice. The control unit 46A sends data indicating user input accepted by the touch panel 38A and microphone 38B to the data processing device 12. The data processing device 12 has a specific processing unit 290 (see FIG. 2) that acquires data indicating user input.

The output device 40 includes a display 40A and a speaker 40B, among others, and presents data to the user by outputting it in a perceptible form (e.g., audio and/or text). The display 40A displays visible information such as text and images according to instructions from the processor 46. The speaker 40B outputs audio according to instructions from the processor 46. The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors.

The communication I/F 44 is connected to the network 54. The communication I/F 44 and 26 manage the exchange of various information between the processor 46 and the processor 28 via the network 54.

FIG. 2 shows an example of the main functions of the data processing device 12 and the smart device 14.

As shown in FIG. 2, specific processing is performed in the data processing device 12 by the processor 28. The storage 32 stores a specific processing program 56. The specific processing program 56 is an example of a "program" related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290. The specific processing unit 290 can estimate the user's emotions using the emotion identification model 59 and perform specific processing using the user's emotions. The emotion estimation function (emotion identification function) using the emotion identification model 59 includes estimating and predicting the user's emotions, but is not limited to such examples. Furthermore, emotion estimation and prediction may include, for example, emotion analysis.

In the smart device 14, specific processing is performed by the processor 46. The storage 50 stores a specific processing program 60. The specific processing program 60 is used in conjunction with the specific processing program 56 by the data processing system 10. The processor 46 reads the specific processing program 60 from the storage 50 and executes it on the RAM 48. The specific processing is realized by the processor 46 operating as a control unit 46A according to the specific processing program 60 executed on the RAM 48. The smart device 14 may also have similar data generation models and emotion identification models as the data generation model 58 and emotion identification model 59, and perform the same processing as the specific processing unit 290 using these models.

Other devices besides the data processing device 12 may have the data generation model 58. For example, a server device (e.g., a generation server) may have the data generation model 58. In this case, the data processing device 12 communicates with the server device having the data generation model 58 to obtain processing results (e.g., prediction results) using the data generation model 58. The data processing device 12 may be a server device or a terminal device owned by the user (e.g., a mobile phone, robot, home appliance, etc.). Next, an example of processing by the data processing system 10 according to the first embodiment will be described.

### [Example 1 of Embodiment]

The design automation system according to the embodiment of the present invention is a system that automates the design of station buildings that meet standards by incorporating the latest policies. This design automation system acquires the latest policies and automatically performs the design of station buildings based on the acquired policies. This design process is performed using AI, and a design that meets the standards is generated. As a result, design efficiency and accuracy are improved. For example, the design automation system acquires the latest policies. Since policies are updated periodically, it is important to always acquire the latest information. For example, the latest policies such as the Building Standards Act and disaster prevention standards are acquired. This information is input to the AI. Next, the design automation system automatically performs the design of station buildings based on the acquired policies. The AI analyzes the acquired policies and generates a design that meets the standards. For example, based on the Building Standards Act, design is performed taking into account earthquake resistance and fire resistance. In addition, based on disaster prevention standards, evacuation routes and the arrangement of emergency equipment are designed. The generated design is verified again by the AI to confirm whether it meets the standards. As a result, the accuracy of the design is improved, and a design that meets the standards is reliably generated. Thus, design efficiency and accuracy are improved. Designers no longer need to manually check the standards, and the design process is greatly shortened. Furthermore, automation by AI improves the accuracy of the design and ensures that a design meeting the standards is reliably generated. For example, since design taking into account earthquake resistance and fire resistance is performed automatically, design mistakes are reduced and safety is improved. Thus, the design automation system can achieve improved design efficiency and accuracy.

The design automation system according to the embodiment includes an acquisition unit, a design unit, and a verification unit. The acquisition unit acquires the latest policy. The acquisition unit, for example, periodically acquires the latest policies such as the Building Standards Act and disaster prevention standards. The acquisition unit, for example, automatically acquires the latest policies via the Internet. In addition, the acquisition unit can monitor policy update information and immediately acquire the latest policy when it is published. Furthermore, the acquisition unit can allow the user to set the frequency of policy acquisition. For example, the acquisition unit can set the acquisition frequency to daily, weekly, monthly, etc. The design unit automatically performs design based on the policy acquired by the acquisition unit. The design unit, for example, performs design taking into account earthquake resistance and fire resistance. The design unit, for example, performs design taking into account earthquake resistance based on the Building Standards Act. In addition, the design unit can also perform design taking into account fire resistance. The design unit, for example, designs evacuation routes and the arrangement of emergency equipment based on disaster prevention standards. The design unit, for example, designs the width of evacuation routes and the locations of emergency equipment. The design unit performs design using AI. The design unit, for example, has the AI analyze the policies and generate a design that meets the standards. The design unit, for example, has the AI perform design taking into account earthquake resistance and fire resistance based on the Building Standards Act. The design unit, for example, has the AI design evacuation routes and the arrangement of emergency equipment based on disaster prevention standards. The verification unit verifies the design generated by the design unit. The verification unit, for example, verifies whether the generated design meets the standards. The verification unit, for example, verifies the design using AI. The verification unit, for example, has the AI analyze the generated design and confirm whether it meets the standards. The verification unit, for example, has the AI verify the design based on the Building Standards Act and disaster prevention standards. Thus, the design automation system according to the embodiment can automate the design of station buildings that meet standards by incorporating the latest policies, thereby improving design efficiency and accuracy.

The acquisition unit acquires the latest policy. The acquisition unit, for example, periodically acquires the latest policies such as the Building Standards Act and disaster prevention standards. Specifically, the acquisition unit is equipped with a function to access the official websites of various laws and standards via the Internet and automatically download the latest policies. This eliminates the need for manual policy confirmation work and ensures that the latest information is always maintained. In addition, the acquisition unit has a dedicated module for monitoring policy update information, and can receive immediate notifications when policies are updated, for example, by using RSS feeds or APIs. Furthermore, the acquisition unit can acquire policies based on the acquisition frequency set by the user. For example, the user can select the acquisition frequency such as daily, weekly, or monthly on the settings screen of the acquisition unit. This enables flexible policy acquisition according to the user's needs. The acquisition unit stores the acquired policies in a database so that the design unit and verification unit can access them. As a result, the entire system can utilize consistent and up-to-date policies.

The design unit automatically performs design based on the policy acquired by the acquisition unit. The design unit, for example, performs design taking into account earthquake resistance and fire resistance. Specifically, the design unit uses AI to analyze the policies and generate a design that meets the standards. The AI uses natural language processing technology to understand the content of the policies and extract the requirements necessary for design. For example, when performing design taking into account earthquake resistance based on the Building Standards Act, the AI automatically determines the structure of the building, selection of materials, arrangement of seismic reinforcements, and so on. In addition, when performing design taking into account fire resistance, the AI arranges firewalls, designs evacuation routes, arranges emergency equipment, and so on. The design unit, for example, designs evacuation routes and the arrangement of emergency equipment based on disaster prevention standards. Specifically, the AI designs the width of evacuation routes and the locations of emergency equipment, and performs simulations to determine the optimal arrangement. The design unit visualizes the generated design as a 3D model so that the user can check it. As a result, the design unit can automatically perform efficient and highly accurate design. Furthermore, the design unit can receive feedback from the user and modify the design content. For example, if the user wants to add specific design requirements, the design unit generates a new design reflecting those requirements. Thus, the design unit can provide flexible design according to the user's needs.

The verification unit verifies the design generated by the design unit. The verification unit, for example, verifies whether the generated design meets the standards. Specifically, the verification unit verifies the design using AI. The AI analyzes the design data and checks whether the design is properly performed based on the Building Standards Act and disaster prevention standards. For example, in the verification of earthquake resistance, the AI performs structural analysis of the building, simulates the response during an earthquake, and evaluates the seismic performance. In the verification of fire resistance, the AI performs fire simulations and checks whether the arrangement of firewalls and evacuation routes is appropriate. Furthermore, the verification unit refers to the latest policy information provided by the acquisition unit to confirm whether the design complies with the latest policies. As a result, the verification unit can ensure that the design always meets the latest standards. The verification unit generates a report of the verification results and provides it to the user. The report describes in detail the conformity of the design and points for improvement, and the user can use this as a basis for modifying or improving the design. Furthermore, the verification unit stores past verification results in a database for future reference in design. Thus, the verification unit can continuously improve the quality of design.

The acquisition unit can periodically acquire the latest policies such as the Building Standards Act and disaster prevention standards. The acquisition unit, for example, automatically acquires the latest policies via the Internet. The acquisition unit, for example, can monitor policy update information and immediately acquire the latest policy when it is published. The acquisition unit, for example, can allow the user to set the frequency of policy acquisition. For example, the acquisition unit can set the acquisition frequency to daily, weekly, monthly, etc. As a result, by periodically acquiring the latest policies, it is possible to always perform design based on the latest standards. Some or all of the above-described processing in the acquisition unit may be performed using AI or may be performed without using AI. For example, the acquisition unit can input policy data acquired from the Internet to a generative AI and have the generative AI perform policy analysis.

The design unit can perform design taking into account earthquake resistance and fire resistance based on the acquired policy. The design unit, for example, performs design taking into account earthquake resistance based on the Building Standards Act. The design unit, for example, can also perform design taking into account fire resistance. The design unit, for example, performs design using AI. The design unit, for example, has the AI analyze the policies and generate a design that meets the standards. The design unit, for example, has the AI perform design taking into account earthquake resistance and fire resistance based on the Building Standards Act. As a result, by performing design taking into account earthquake resistance and fire resistance, it is possible to achieve highly safe design. Some or all of the above-described processing in the design unit may be performed using AI or may be performed without using AI. For example, the design unit can input the acquired policy data to a generative AI and have the generative AI perform design generation.

The design unit can design evacuation routes and the arrangement of emergency equipment based on disaster prevention standards. The design unit, for example, designs the width of evacuation routes and the locations of emergency equipment based on disaster prevention standards. The design unit, for example, performs design using AI. The design unit, for example, has the AI analyze the policies and generate a design that meets the standards. The design unit, for example, has the AI design evacuation routes and the arrangement of emergency equipment based on disaster prevention standards. As a result, by performing design based on disaster prevention standards, safety in the event of a disaster is improved. Some or all of the above-described processing in the design unit may be performed using AI or may be performed without using AI. For example, the design unit can input the acquired policy data to a generative AI and have the generative AI perform design generation.

The verification unit can verify whether the generated design meets the standards. The verification unit, for example, verifies whether the generated design meets the standards. The verification unit, for example, verifies the design using AI. The verification unit, for example, has the AI analyze the generated design and confirm whether it meets the standards. The verification unit, for example, has the AI verify the design based on the Building Standards Act and disaster prevention standards. As a result, by verifying whether the design meets the standards, the accuracy of the design is improved. Some or all of the above-described processing in the verification unit may be performed using AI or may be performed without using AI. For example, the verification unit can input the generated design data to a generative AI and have the generative AI perform design verification.

The acquisition unit can analyze the history of past policy changes at the time of policy acquisition and select an optimal acquisition method. The acquisition unit, for example, analyzes the history of past policy changes and preferentially acquires policies that are frequently changed. The acquisition unit, for example, analyzes patterns of policy changes and acquires policies at times when changes are predicted. The acquisition unit, for example, identifies highly important policies from the history of past policy changes and preferentially acquires them. As a result, by analyzing the history of past policy changes, it is possible to select the optimal policy acquisition method and efficiently acquire policies. Some or all of the above-described processing in the acquisition unit may be performed using AI or may be performed without using AI. For example, the acquisition unit can input past policy change history data to a generative AI and have the generative AI select the optimal acquisition method.

The acquisition unit can perform filtering at the time of policy acquisition in consideration of region-specific building standards and disaster prevention standards. The acquisition unit, for example, considers region-specific building standards and acquires only the policies for the relevant region. The acquisition unit, for example, considers region-specific disaster prevention standards and acquires only the policies for the relevant region. The acquisition unit, for example, filters region-specific standards and acquires only the necessary policies. As a result, by considering region-specific standards, it is possible to acquire policies suitable for the relevant region and improve the accuracy of design. Some or all of the above-described processing in the acquisition unit may be performed using AI or may be performed without using AI. For example, the acquisition unit can input region-specific standard data to a generative AI and have the generative AI perform filtering.

The acquisition unit can preferentially acquire highly relevant policies at the time of policy acquisition in consideration of the user's geographic location information. The acquisition unit, for example, preferentially acquires policies for the relevant region based on the user's current location. The acquisition unit, for example, acquires policies for highly relevant regions based on the user's past movement history. The acquisition unit, for example, acquires policies for highly relevant regions in consideration of the user's future movement plans. As a result, by considering the user's geographic location information, it is possible to preferentially acquire highly relevant policies and improve the accuracy of design. Some or all of the above-described processing in the acquisition unit may be performed using AI or may be performed without using AI. For example, the acquisition unit can input the user's geographic location information data to a generative AI and have the generative AI select highly relevant policies.

The acquisition unit can analyze the user's social media activity at the time of policy acquisition and acquire relevant policies. The acquisition unit, for example, analyzes the content of the user's social media posts and acquires relevant policies. The acquisition unit, for example, analyzes the user's followers and followed accounts on social media and acquires relevant policies. The acquisition unit, for example, analyzes the user's activity time on social media and acquires policies at the optimal timing. As a result, by analyzing the user's social media activity, it is possible to efficiently acquire relevant policies and improve the accuracy of design. Some or all of the above-described processing in the acquisition unit may be performed using AI or may be performed without using AI. For example, the acquisition unit can input the user's social media data to a generative AI and have the generative AI select relevant policies.

The design unit can adjust the level of detail of the design based on the importance of the policy at the time of design. The design unit, for example, performs detailed design based on highly important policies. The design unit, for example, performs simplified design based on less important policies. The design unit, for example, adjusts the level of detail of the design stepwise according to the importance of the policy. As a result, by adjusting the level of detail of the design based on the importance of the policy, efficient design is possible. Some or all of the above-described processing in the design unit may be performed using AI or may be performed without using AI. For example, the design unit can input policy data to a generative AI and have the generative AI adjust the level of detail of the design.

The design unit can apply different design algorithms according to the intended use of the building at the time of design. The design unit, for example, applies a design algorithm that emphasizes habitability to residential buildings. The design unit, for example, applies a design algorithm that emphasizes profitability to commercial buildings. The design unit, for example, applies a design algorithm that emphasizes safety to public facilities. As a result, by applying design algorithms according to the intended use of the building, it is possible to achieve design suitable for the intended use. Some or all of the above-described processing in the design unit may be performed using AI or may be performed without using AI. For example, the design unit can input building use data to a generative AI and have the generative AI select the design algorithm to be applied.

The design unit can determine the priority of the design based on the timing of policy updates at the time of design. The design unit, for example, determines the priority of the design based on the latest policy. The design unit, for example, considers the timing of policy updates and preferentially reflects highly important policies in the design. The design unit, for example, adjusts the priority of the design based on the frequency of policy updates. As a result, by determining the priority of the design based on the timing of policy updates, it is possible to perform design based on the latest standards. Some or all of the above-described processing in the design unit may be performed using AI or may be performed without using AI. For example, the design unit can input policy update timing data to a generative AI and have the generative AI determine the priority of the design.

The design unit can adjust the order of design based on the relevance of the buildings at the time of design. The design unit, for example, adjusts the order of design based on the intended use of the buildings. The design unit, for example, adjusts the order of design based on the scale of the buildings. The design unit, for example, adjusts the order of design based on the location conditions of the buildings. As a result, by adjusting the order of design based on the relevance of the buildings, efficient design is possible. Some or all of the above-described processing in the design unit may be performed using AI or may be performed without using AI. For example, the design unit can input building relevance data to a generative AI and have the generative AI adjust the order of design.

The verification unit can improve the accuracy of verification by considering the interrelationships of the designs at the time of verification. The verification unit, for example, analyzes the interrelationships of the designs and checks for consistency. The verification unit, for example, considers the interrelationships of the designs and detects inconsistencies. The verification unit, for example, selects the optimal verification method based on the interrelationships of the designs. As a result, by considering the interrelationships of the designs, the accuracy of verification is improved. Some or all of the above-described processing in the verification unit may be performed using AI or may be performed without using AI. For example, the verification unit can input design interrelationship data to a generative AI and have the generative AI improve the accuracy of verification.

The verification unit can perform verification in consideration of the attribute information of the designer at the time of verification. The verification unit, for example, considers the designer's years of experience and adjusts the rigor of verification. The verification unit, for example, considers the designer's area of expertise and applies appropriate verification criteria. The verification unit, for example, adjusts the focus of verification based on the designer's past achievements. As a result, by considering the attribute information of the designer, appropriate verification is performed. Some or all of the above-described processing in the verification unit may be performed using AI or may be performed without using AI. For example, the verification unit can input designer attribute information data to a generative AI and have the generative AI perform verification adjustment.

The verification unit can perform verification in consideration of the geographical distribution of the designs at the time of verification. The verification unit, for example, considers the geographical distribution of the designs and performs verification based on region-specific standards. The verification unit, for example, analyzes the geographical distribution of the designs and performs verification in consideration of region-specific characteristics. The verification unit, for example, selects the optimal verification method based on the geographical distribution of the designs. As a result, by considering the geographical distribution of the designs, verification conforming to region-specific standards is performed. Some or all of the above-described processing in the verification unit may be performed using AI or may be performed without using AI. For example, the verification unit can input design geographical distribution data to a generative AI and have the generative AI perform verification adjustment.

The verification unit can improve the accuracy of verification by referring to related literature of the designs at the time of verification. The verification unit, for example, refers to related literature of the designs and checks for conformity to standards. The verification unit, for example, improves the accuracy of verification based on related literature of the designs. The verification unit, for example, analyzes related literature of the designs and selects the optimal verification method. As a result, by referring to related literature of the designs, the accuracy of verification is improved. Some or all of the above-described processing in the verification unit may be performed using AI or may be performed without using AI. For example, the verification unit can input design related literature data to a generative AI and have the generative AI improve the accuracy of verification.

The system according to the embodiment is not limited to the above-described examples, and various modifications are possible, for example, as follows.

The design automation system may further include a history analysis unit that optimizes design in consideration of the user's past design history. The history analysis unit, for example, analyzes data from past design projects and identifies successful and unsuccessful design patterns. The history analysis unit, for example, collects user feedback from past design projects and extracts points for improvement in the design. The history analysis unit, for example, proposes optimal design methods based on data from past design projects. As a result, by considering past design history, the accuracy and efficiency of design are improved, and design that meets the user's needs is provided.

The design automation system may further include a progress monitoring unit that monitors the progress of design in real time and notifies the user. The progress monitoring unit, for example, monitors each step of the design process and notifies the user of the progress. The progress monitoring unit, for example, sends an alert to the user when a delay occurs in the design. The progress monitoring unit, for example, visually displays the progress of the design in graphs or charts so that the user can easily understand it. As a result, by grasping the progress of design in real time, the efficiency of the design process is improved and the user's stress is reduced.

The design automation system may further include a quality evaluation unit that evaluates the quality of the design. The quality evaluation unit, for example, evaluates each element of the design and calculates a quality score. The quality evaluation unit, for example, evaluates the durability and safety of the design and provides feedback to the user. The quality evaluation unit, for example, evaluates the aesthetics and functionality of the design and proposes points for improvement. As a result, by evaluating the quality of the design, the accuracy and reliability of the design are improved, and valuable design is provided to the user.

The design automation system may further include a cost optimization unit that optimizes the cost of the design. The cost optimization unit, for example, analyzes the cost of each element of the design and proposes cost reduction measures. The cost optimization unit, for example, proposes cost-effective options in the selection of materials and construction methods. The cost optimization unit, for example, monitors the total cost of the design in real time and supports design within the budget. As a result, by optimizing the cost of the design, economical design is realized and the user's cost burden is reduced.

The design automation system may further include an environmental evaluation unit that evaluates the environmental impact of the design. The environmental evaluation unit, for example, evaluates the impact of each element of the design on the environment and proposes measures to minimize environmental load. The environmental evaluation unit, for example, evaluates energy efficiency and resource usage and recommends environmentally friendly design. The environmental evaluation unit, for example, evaluates the environmental impact throughout the entire life cycle of the design and supports sustainable design. As a result, by evaluating the environmental impact of the design, sustainable design is realized and environmental protection is promoted.

The following is a brief description of the processing flow of Example 1 of the Embodiment.

Step 1: The acquisition unit acquires the latest policy. The acquisition unit, for example, periodically acquires the latest policies such as the Building Standards Act and disaster prevention standards. The acquisition unit automatically acquires the latest policies via the Internet, monitors policy update information, and can immediately acquire the latest policy when it is published. In addition, the acquisition unit can allow the user to set the frequency of policy acquisition, and can set the acquisition frequency to daily, weekly, monthly, etc.

Step 2: The design unit automatically performs design based on the policy acquired by the acquisition unit. The design unit performs design taking into account earthquake resistance and fire resistance, and designs earthquake resistance based on the Building Standards Act and the arrangement of evacuation routes and emergency equipment based on disaster prevention standards. The design unit analyzes the policies using AI and generates a design that meets the standards.

Step 3: The verification unit verifies the design generated by the design unit. The verification unit verifies whether the generated design meets the standards, analyzes the design using AI, and verifies the design based on the Building Standards Act and disaster prevention standards.

### [Example 2 of Embodiment]

The design automation system according to the embodiment of the present invention is a system that automates the design of station buildings that meet standards by incorporating the latest policies. This design automation system acquires the latest policies and automatically performs the design of station buildings based on the acquired policies. This design process is performed using AI, and a design that meets the standards is generated. As a result, design efficiency and accuracy are improved. For example, the design automation system acquires the latest policies. Since policies are updated periodically, it is important to always acquire the latest information. For example, the latest policies such as the Building Standards Act and disaster prevention standards are acquired. This information is input to the AI. Next, the design automation system automatically performs the design of station buildings based on the acquired policies. The AI analyzes the acquired policies and generates a design that meets the standards. For example, based on the Building Standards Act, design is performed taking into account earthquake resistance and fire resistance. In addition, based on disaster prevention standards, evacuation routes and the arrangement of emergency equipment are designed. The generated design is verified again by the AI to confirm whether it meets the standards. As a result, the accuracy of the design is improved, and a design that meets the standards is reliably generated. Thus, design efficiency and accuracy are improved. Designers no longer need to manually check the standards, and the design process is greatly shortened. Furthermore, automation by AI improves the accuracy of the design and ensures that a design meeting the standards is reliably generated. For example, since design taking into account earthquake resistance and fire resistance is performed automatically, design mistakes are reduced and safety is improved. Thus, the design automation system can achieve improved design efficiency and accuracy.

The design automation system according to the embodiment includes an acquisition unit, a design unit, and a verification unit. The acquisition unit acquires the latest policy. The acquisition unit, for example, periodically acquires the latest policies such as the Building Standards Act and disaster prevention standards. The acquisition unit, for example, automatically acquires the latest policies via the Internet. In addition, the acquisition unit can monitor policy update information and immediately acquire the latest policy when it is published. Furthermore, the acquisition unit can allow the user to set the frequency of policy acquisition. For example, the acquisition unit can set the acquisition frequency to daily, weekly, monthly, etc. The design unit automatically performs design based on the policy acquired by the acquisition unit. The design unit, for example, performs design taking into account earthquake resistance and fire resistance. The design unit, for example, performs design taking into account earthquake resistance based on the Building Standards Act. In addition, the design unit can also perform design taking into account fire resistance. The design unit, for example, designs evacuation routes and the arrangement of emergency equipment based on disaster prevention standards. The design unit, for example, designs the width of evacuation routes and the locations of emergency equipment. The design unit performs design using AI. The design unit, for example, has the AI analyze the policies and generate a design that meets the standards. The design unit, for example, has the AI perform design taking into account earthquake resistance and fire resistance based on the Building Standards Act. The design unit, for example, has the AI design evacuation routes and the arrangement of emergency equipment based on disaster prevention standards. The verification unit verifies the design generated by the design unit. The verification unit, for example, verifies whether the generated design meets the standards. The verification unit, for example, verifies the design using AI. The verification unit, for example, has the AI analyze the generated design and confirm whether it meets the standards. The verification unit, for example, has the AI verify the design based on the Building Standards Act and disaster prevention standards. Thus, the design automation system according to the embodiment can automate the design of station buildings that meet standards by incorporating the latest policies, thereby improving design efficiency and accuracy.

The acquisition unit acquires the latest policy. The acquisition unit, for example, periodically acquires the latest policies such as the Building Standards Act and disaster prevention standards. Specifically, the acquisition unit is equipped with a function to access the official websites of various laws and standards via the Internet and automatically download the latest policies. This eliminates the need for manual policy confirmation work and ensures that the latest information is always maintained. In addition, the acquisition unit has a dedicated module for monitoring policy update information, and can receive immediate notifications when policies are updated, for example, by using RSS feeds or APIs. Furthermore, the acquisition unit can acquire policies based on the acquisition frequency set by the user. For example, the user can select the acquisition frequency such as daily, weekly, or monthly on the settings screen of the acquisition unit. This enables flexible policy acquisition according to the user's needs. The acquisition unit stores the acquired policies in a database so that the design unit and verification unit can access them. As a result, the entire system can utilize consistent and up-to-date policies.

The design unit automatically performs design based on the policy acquired by the acquisition unit. The design unit, for example, performs design taking into account earthquake resistance and fire resistance. Specifically, the design unit uses AI to analyze the policies and generate a design that meets the standards. The AI uses natural language processing technology to understand the content of the policies and extract the requirements necessary for design. For example, when performing design taking into account earthquake resistance based on the Building Standards Act, the AI automatically determines the structure of the building, selection of materials, arrangement of seismic reinforcements, and so on. In addition, when performing design taking into account fire resistance, the AI arranges firewalls, designs evacuation routes, arranges emergency equipment, and so on. The design unit, for example, designs evacuation routes and the arrangement of emergency equipment based on disaster prevention standards. Specifically, the AI designs the width of evacuation routes and the locations of emergency equipment, and performs simulations to determine the optimal arrangement. The design unit visualizes the generated design as a 3D model so that the user can check it. As a result, the design unit can automatically perform efficient and highly accurate design. Furthermore, the design unit can receive feedback from the user and modify the design content. For example, if the user wants to add specific design requirements, the design unit generates a new design reflecting those requirements. Thus, the design unit can provide flexible design according to the user's needs.

The verification unit verifies the design generated by the design unit. The verification unit, for example, verifies whether the generated design meets the standards. Specifically, the verification unit verifies the design using AI. The AI analyzes the design data and checks whether the design is properly performed based on the Building Standards Act and disaster prevention standards. For example, in the verification of earthquake resistance, the AI performs structural analysis of the building, simulates the response during an earthquake, and evaluates the seismic performance. In the verification of fire resistance, the AI performs fire simulations and checks whether the arrangement of firewalls and evacuation routes is appropriate. Furthermore, the verification unit refers to the latest policy information provided by the acquisition unit to confirm whether the design complies with the latest policies. As a result, the verification unit can ensure that the design always meets the latest standards. The verification unit generates a report of the verification results and provides it to the user. The report describes in detail the conformity of the design and points for improvement, and the user can use this as a basis for modifying or improving the design. Furthermore, the verification unit stores past verification results in a database for future reference in design. Thus, the verification unit can continuously improve the quality of design.

The acquisition unit can periodically acquire the latest policies such as the Building Standards Act and disaster prevention standards. The acquisition unit, for example, automatically acquires the latest policies via the Internet. The acquisition unit, for example, can monitor policy update information and immediately acquire the latest policy when it is published. The acquisition unit, for example, can allow the user to set the frequency of policy acquisition. For example, the acquisition unit can set the acquisition frequency to daily, weekly, monthly, etc. As a result, by periodically acquiring the latest policies, it is possible to always perform design based on the latest standards. Some or all of the above-described processing in the acquisition unit may be performed using AI or may be performed without using AI. For example, the acquisition unit can input policy data acquired from the Internet to a generative AI and have the generative AI perform policy analysis.

The design unit can perform design taking into account earthquake resistance and fire resistance based on the acquired policy. The design unit, for example, performs design taking into account earthquake resistance based on the Building Standards Act. The design unit, for example, can also perform design taking into account fire resistance. The design unit, for example, performs design using AI. The design unit, for example, has the AI analyze the policies and generate a design that meets the standards. The design unit, for example, has the AI perform design taking into account earthquake resistance and fire resistance based on the Building Standards Act. As a result, by performing design taking into account earthquake resistance and fire resistance, it is possible to achieve highly safe design. Some or all of the above-described processing in the design unit may be performed using AI or may be performed without using AI. For example, the design unit can input the acquired policy data to a generative AI and have the generative AI perform design generation.

The design unit can design evacuation routes and the arrangement of emergency equipment based on disaster prevention standards. The design unit, for example, designs the width of evacuation routes and the locations of emergency equipment based on disaster prevention standards. The design unit, for example, performs design using AI. The design unit, for example, has the AI analyze the policies and generate a design that meets the standards. The design unit, for example, has the AI design evacuation routes and the arrangement of emergency equipment based on disaster prevention standards. As a result, by performing design based on disaster prevention standards, safety in the event of a disaster is improved. Some or all of the above-described processing in the design unit may be performed using AI or may be performed without using AI. For example, the design unit can input the acquired policy data to a generative AI and have the generative AI perform design generation.

The verification unit can verify whether the generated design meets the standards. The verification unit, for example, verifies whether the generated design meets the standards. The verification unit, for example, verifies the design using AI. The verification unit, for example, has the AI analyze the generated design and confirm whether it meets the standards. The verification unit, for example, has the AI verify the design based on the Building Standards Act and disaster prevention standards. As a result, by verifying whether the design meets the standards, the accuracy of the design is improved. Some or all of the above-described processing in the verification unit may be performed using AI or may be performed without using AI. For example, the verification unit can input the generated design data to a generative AI and have the generative AI perform design verification.

The acquisition unit can estimate the user's emotion and adjust the timing of policy acquisition based on the estimated user's emotion. For example, if the user is feeling stressed, the acquisition of policies is delayed and acquisition is performed when the user is relaxed. If the user is in a hurry, policy acquisition is performed quickly and the design process is started immediately. If the user is relaxed, policy acquisition is performed periodically to always maintain the latest information. As a result, by adjusting the timing of policy acquisition according to the user's emotion, the user's stress is reduced and efficient policy acquisition is possible. Emotion estimation is realized, for example, by using an emotion engine or a generative AI with an emotion estimation function. The generative AI may be a text generation AI (e.g., LLM) or a multimodal generative AI, but is not limited to such examples. Some or all of the above-described processing in the acquisition unit may be performed using AI or may be performed without using AI. For example, the acquisition unit can input the user's emotion data to a generative AI and have the generative AI perform emotion estimation.

The acquisition unit can analyze the history of past policy changes at the time of policy acquisition and select an optimal acquisition method. The acquisition unit, for example, analyzes the history of past policy changes and preferentially acquires policies that are frequently changed. The acquisition unit, for example, analyzes patterns of policy changes and acquires policies at times when changes are predicted. The acquisition unit, for example, identifies highly important policies from the history of past policy changes and preferentially acquires them. As a result, by analyzing the history of past policy changes, it is possible to select the optimal policy acquisition method and efficiently acquire policies. Some or all of the above-described processing in the acquisition unit may be performed using AI or may be performed without using AI. For example, the acquisition unit can input past policy change history data to a generative AI and have the generative AI select the optimal acquisition method.

The acquisition unit can perform filtering at the time of policy acquisition in consideration of region-specific building standards and disaster prevention standards. The acquisition unit, for example, considers region-specific building standards and acquires only the policies for the relevant region. The acquisition unit, for example, considers region-specific disaster prevention standards and acquires only the policies for the relevant region. The acquisition unit, for example, filters region-specific standards and acquires only the necessary policies. As a result, by considering region-specific standards, it is possible to acquire policies suitable for the relevant region and improve the accuracy of design. Some or all of the above-described processing in the acquisition unit may be performed using AI or may be performed without using AI. For example, the acquisition unit can input region-specific standard data to a generative AI and have the generative AI perform filtering.

The acquisition unit can estimate the user's emotion and determine the priority of policies to be acquired based on the estimated user's emotion. For example, if the user is feeling stressed, policies of low importance are postponed and policies of high importance are preferentially acquired. If the user is relaxed, all policies are acquired evenly. If the user is in a hurry, the most important policies are preferentially acquired. As a result, by determining the priority of policies according to the user's emotion, efficient policy acquisition is possible. Emotion estimation is realized, for example, by using an emotion engine or a generative AI with an emotion estimation function. The generative AI may be a text generation AI (e.g., LLM) or a multimodal generative AI, but is not limited to such examples. Some or all of the above-described processing in the acquisition unit may be performed using AI or may be performed without using AI. For example, the acquisition unit can input the user's emotion data to a generative AI and have the generative AI perform emotion estimation.

The acquisition unit can preferentially acquire highly relevant policies at the time of policy acquisition in consideration of the user's geographic location information. The acquisition unit, for example, preferentially acquires policies for the relevant region based on the user's current location. The acquisition unit, for example, acquires policies for highly relevant regions based on the user's past movement history. The acquisition unit, for example, acquires policies for highly relevant regions in consideration of the user's future movement plans. As a result, by considering the user's geographic location information, it is possible to preferentially acquire highly relevant policies and improve the accuracy of design. Some or all of the above-described processing in the acquisition unit may be performed using AI or may be performed without using AI. For example, the acquisition unit can input the user's geographic location information data to a generative AI and have the generative AI select highly relevant policies.

The acquisition unit can analyze the user's social media activity at the time of policy acquisition and acquire relevant policies. The acquisition unit, for example, analyzes the content of the user's social media posts and acquires relevant policies. The acquisition unit, for example, analyzes the user's followers and followed accounts on social media and acquires relevant policies. The acquisition unit, for example, analyzes the user's activity time on social media and acquires policies at the optimal timing. As a result, by analyzing the user's social media activity, it is possible to efficiently acquire relevant policies and improve the accuracy of design. Some or all of the above-described processing in the acquisition unit may be performed using AI or may be performed without using AI. For example, the acquisition unit can input the user's social media data to a generative AI and have the generative AI select relevant policies.

The design unit can estimate the user's emotion and adjust the method of expressing the design based on the estimated user's emotion. For example, if the user is feeling stressed, a simple and highly visible design is provided. If the user is relaxed, a detailed design is provided. If the user is in a hurry, a design focusing on key points is provided. As a result, by adjusting the method of expressing the design according to the user's emotion, a design that is easy for the user to understand is provided. Emotion estimation is realized, for example, by using an emotion engine or a generative AI with an emotion estimation function. The generative AI may be a text generation AI (e.g., LLM) or a multimodal generative AI, but is not limited to such examples. Some or all of the above-described processing in the design unit may be performed using AI or may be performed without using AI. For example, the design unit can input the user's emotion data to a generative AI and have the generative AI perform emotion estimation.

The design unit can adjust the level of detail of the design based on the importance of the policy at the time of design. The design unit, for example, performs detailed design based on highly important policies. The design unit, for example, performs simplified design based on less important policies. The design unit, for example, adjusts the level of detail of the design stepwise according to the importance of the policy. As a result, by adjusting the level of detail of the design based on the importance of the policy, efficient design is possible. Some or all of the above-described processing in the design unit may be performed using AI or may be performed without using AI. For example, the design unit can input policy data to a generative AI and have the generative AI adjust the level of detail of the design.

The design unit can apply different design algorithms according to the intended use of the building at the time of design. The design unit, for example, applies a design algorithm that emphasizes habitability to residential buildings. The design unit, for example, applies a design algorithm that emphasizes profitability to commercial buildings. The design unit, for example, applies a design algorithm that emphasizes safety to public facilities. As a result, by applying design algorithms according to the intended use of the building, it is possible to achieve design suitable for the intended use. Some or all of the above-described processing in the design unit may be performed using AI or may be performed without using AI. For example, the design unit can input building use data to a generative AI and have the generative AI select the design algorithm to be applied.

The design unit can estimate the user's emotion and adjust the length of the design based on the estimated user's emotion. For example, if the user is feeling stressed, the length of the design is shortened and a concise design is provided. If the user is relaxed, a detailed design is provided. If the user is in a hurry, a design focusing on key points is provided. As a result, by adjusting the length of the design according to the user's emotion, a design appropriate for the user is provided. Emotion estimation is realized, for example, by using an emotion engine or a generative AI with an emotion estimation function. The generative AI may be a text generation AI (e.g., LLM) or a multimodal generative AI, but is not limited to such examples. Some or all of the above-described processing in the design unit may be performed using AI or may be performed without using AI. For example, the design unit can input the user's emotion data to a generative AI and have the generative AI perform emotion estimation.

The design unit can determine the priority of the design based on the timing of policy updates at the time of design. The design unit, for example, determines the priority of the design based on the latest policy. The design unit, for example, considers the timing of policy updates and preferentially reflects highly important policies in the design. The design unit, for example, adjusts the priority of the design based on the frequency of policy updates. As a result, by determining the priority of the design based on the timing of policy updates, it is possible to perform design based on the latest standards. Some or all of the above-described processing in the design unit may be performed using AI or may be performed without using AI. For example, the design unit can input policy update timing data to a generative AI and have the generative AI determine the priority of the design.

The design unit can adjust the order of design based on the relevance of the buildings at the time of design. The design unit, for example, adjusts the order of design based on the intended use of the buildings. The design unit, for example, adjusts the order of design based on the scale of the buildings. The design unit, for example, adjusts the order of design based on the location conditions of the buildings. As a result, by adjusting the order of design based on the relevance of the buildings, efficient design is possible. Some or all of the above-described processing in the design unit may be performed using AI or may be performed without using AI. For example, the design unit can input building relevance data to a generative AI and have the generative AI adjust the order of design.

The verification unit can estimate the user's emotion and adjust the verification criteria based on the estimated user's emotion. For example, if the user is feeling stressed, concise verification criteria are provided. If the user is relaxed, detailed verification criteria are provided. If the user is in a hurry, verification criteria focusing on key points are provided. As a result, by adjusting the verification criteria according to the user's emotion, verification appropriate for the user is provided. Emotion estimation is realized, for example, by using an emotion engine or a generative AI with an emotion estimation function. The generative AI may be a text generation AI (e.g., LLM) or a multimodal generative AI, but is not limited to such examples. Some or all of the above-described processing in the verification unit may be performed using AI or may be performed without using AI. For example, the verification unit can input the user's emotion data to a generative AI and have the generative AI perform emotion estimation.

The verification unit can improve the accuracy of verification by considering the interrelationships of the designs at the time of verification. The verification unit, for example, analyzes the interrelationships of the designs and checks for consistency. The verification unit, for example, considers the interrelationships of the designs and detects inconsistencies. The verification unit, for example, selects the optimal verification method based on the interrelationships of the designs. As a result, by considering the interrelationships of the designs, the accuracy of verification is improved. Some or all of the above-described processing in the verification unit may be performed using AI or may be performed without using AI. For example, the verification unit can input design interrelationship data to a generative AI and have the generative AI improve the accuracy of verification.

The verification unit can perform verification in consideration of the attribute information of the designer at the time of verification. The verification unit, for example, considers the designer's years of experience and adjusts the rigor of verification. The verification unit, for example, considers the designer's area of expertise and applies appropriate verification criteria. The verification unit, for example, adjusts the focus of verification based on the designer's past achievements. As a result, by considering the attribute information of the designer, appropriate verification is performed. Some or all of the above-described processing in the verification unit may be performed using AI or may be performed without using AI. For example, the verification unit can input designer attribute information data to a generative AI and have the generative AI perform verification adjustment.

The verification unit can estimate the user's emotion and adjust the order in which the results of verification are displayed based on the estimated user's emotion. For example, if the user is feeling stressed, important results are displayed first. If the user is relaxed, detailed results are displayed sequentially. If the user is in a hurry, results focusing on key points are displayed first. As a result, by adjusting the display order of verification results according to the user's emotion, results that are easy for the user to understand are provided. Emotion estimation is realized, for example, by using an emotion engine or a generative AI with an emotion estimation function. The generative AI may be a text generation AI (e.g., LLM) or a multimodal generative AI, but is not limited to such examples. Some or all of the above-described processing in the verification unit may be performed using AI or may be performed without using AI. For example, the verification unit can input the user's emotion data to a generative AI and have the generative AI perform emotion estimation.

The verification unit can perform verification in consideration of the geographical distribution of the designs at the time of verification. The verification unit, for example, considers the geographical distribution of the designs and performs verification based on region-specific standards. The verification unit, for example, analyzes the geographical distribution of the designs and performs verification in consideration of region-specific characteristics. The verification unit, for example, selects the optimal verification method based on the geographical distribution of the designs. As a result, by considering the geographical distribution of the designs, verification conforming to region-specific standards is performed. Some or all of the above-described processing in the verification unit may be performed using AI or may be performed without using AI. For example, the verification unit can input design geographical distribution data to a generative AI and have the generative AI perform verification adjustment.

The verification unit can improve the accuracy of verification by referring to related literature of the designs at the time of verification. The verification unit, for example, refers to related literature of the designs and checks for conformity to standards. The verification unit, for example, improves the accuracy of verification based on related literature of the designs. The verification unit, for example, analyzes related literature of the designs and selects the optimal verification method. As a result, by referring to related literature of the designs, the accuracy of verification is improved. Some or all of the above-described processing in the verification unit may be performed using AI or may be performed without using AI. For example, the verification unit can input design related literature data to a generative AI and have the generative AI improve the accuracy of verification.

The system according to the embodiment is not limited to the above-described examples, and various modifications are possible, for example, as follows.

The design automation system may further include a history analysis unit that optimizes design in consideration of the user's past design history. The history analysis unit, for example, analyzes data from past design projects and identifies successful and unsuccessful design patterns. The history analysis unit, for example, collects user feedback from past design projects and extracts points for improvement in the design. The history analysis unit, for example, proposes optimal design methods based on data from past design projects. As a result, by considering past design history, the accuracy and efficiency of design are improved, and design that meets the user's needs is provided.

The design automation system may further include a progress monitoring unit that monitors the progress of design in real time and notifies the user. The progress monitoring unit, for example, monitors each step of the design process and notifies the user of the progress. The progress monitoring unit, for example, sends an alert to the user when a delay occurs in the design. The progress monitoring unit, for example, visually displays the progress of the design in graphs or charts so that the user can easily understand it. As a result, by grasping the progress of design in real time, the efficiency of the design process is improved and the user's stress is reduced.

The design automation system may further include a quality evaluation unit that evaluates the quality of the design. The quality evaluation unit, for example, evaluates each element of the design and calculates a quality score. The quality evaluation unit, for example, evaluates the durability and safety of the design and provides feedback to the user. The quality evaluation unit, for example, evaluates the aesthetics and functionality of the design and proposes points for improvement. As a result, by evaluating the quality of the design, the accuracy and reliability of the design are improved, and valuable design is provided to the user.

The design automation system may further include a cost optimization unit that optimizes the cost of the design. The cost optimization unit, for example, analyzes the cost of each element of the design and proposes cost reduction measures. The cost optimization unit, for example, proposes cost-effective options in the selection of materials and construction methods. The cost optimization unit, for example, monitors the total cost of the design in real time and supports design within the budget. As a result, by optimizing the cost of the design, economical design is realized and the user's cost burden is reduced.

The design automation system may further include an environmental evaluation unit that evaluates the environmental impact of the design. The environmental evaluation unit, for example, evaluates the impact of each element of the design on the environment and proposes measures to minimize environmental load. The environmental evaluation unit, for example, evaluates energy efficiency and resource usage and recommends environmentally friendly design. The environmental evaluation unit, for example, evaluates the environmental impact throughout the entire life cycle of the design and supports sustainable design. As a result, by evaluating the environmental impact of the design, sustainable design is realized and environmental protection is promoted.

The design automation system can further estimate the user's emotion and adjust the design interface based on the estimated user's emotion. For example, if the user is feeling stressed, a simple and intuitive interface is provided. If the user is relaxed, an interface that displays detailed information is provided. If the user is in a hurry, an interface that prioritizes the display of important information is provided. As a result, by adjusting the interface according to the user's emotion, the user's operability is improved and stress is reduced.

The design automation system can further estimate the user's emotion and adjust the design feedback based on the estimated user's emotion. For example, if the user is feeling stressed, positive feedback is preferentially provided. If the user is relaxed, detailed feedback is provided. If the user is in a hurry, feedback focusing on key points is provided. As a result, by adjusting the feedback according to the user's emotion, user satisfaction is improved and the design process proceeds smoothly.

The design automation system can further estimate the user's emotion and adjust the progress speed of the design based on the estimated user's emotion. For example, if the user is feeling stressed, the progress speed of the design is slowed down and proceeds at a pace that is easy for the user to understand. If the user is relaxed, the progress speed of the design is increased and proceeds efficiently. If the user is in a hurry, the most important parts are prioritized. As a result, by adjusting the progress speed of the design according to the user's emotion, the user's stress is reduced and the design process proceeds efficiently.

The design automation system can further estimate the user's emotion and adjust the notification method of the design based on the estimated user's emotion. For example, if the user is feeling stressed, notifications are kept to a minimum and only important notifications are provided. If the user is relaxed, detailed notifications are provided. If the user is in a hurry, notifications are provided immediately to prompt quick action. As a result, by adjusting the notification method according to the user's emotion, the user's stress is reduced and the design process proceeds smoothly.

The design automation system can further estimate the user's emotion and adjust the review method of the design based on the estimated user's emotion. For example, if the user is feeling stressed, a concise review is provided. If the user is relaxed, a detailed review is provided. If the user is in a hurry, a review focusing on key points is provided. As a result, by adjusting the review method according to the user's emotion, the user's understanding is deepened and the design process proceeds efficiently.

The following is a brief description of the processing flow of Example 2 of the Embodiment.

Step 1: The acquisition unit acquires the latest policy. The acquisition unit, for example, periodically acquires the latest policies such as the Building Standards Act and disaster prevention standards. The acquisition unit automatically acquires the latest policies via the Internet, monitors policy update information, and can immediately acquire the latest policy when it is published. In addition, the acquisition unit can allow the user to set the frequency of policy acquisition, and can set the acquisition frequency to daily, weekly, monthly, etc.

Step 2: The design unit automatically performs design based on the policy acquired by the acquisition unit. The design unit performs design taking into account earthquake resistance and fire resistance, and designs earthquake resistance based on the Building Standards Act and the arrangement of evacuation routes and emergency equipment based on disaster prevention standards. The design unit analyzes the policies using AI and generates a design that meets the standards.

Step 3: The verification unit verifies the design generated by the design unit. The verification unit verifies whether the generated design meets the standards, analyzes the design using AI, and verifies the design based on the Building Standards Act and disaster prevention standards.

The specific processing unit 290 sends the results of specific processing to the smart device 14. In the smart device 14, the control unit 46A causes the output device 40 to output the results of specific processing. The microphone 38B acquires voice indicating user input in response to the results of specific processing. The control unit 46A sends the voice data indicating user input acquired by the microphone 38B to the data processing device 12. In the data processing device 12, the specific processing unit 290 acquires the voice data.

The data generation model 58 is a so-called generative AI (Artificial Intelligence). An example of the data generation model 58 is a generative AI such as ChatGPT (registered trademark) (Internet search <URL: https://openai.com/blog/chatgpt>). The data generation model 58 is obtained by performing deep learning on a neural network. The data generation model 58 receives prompts containing instructions and inference data such as voice data indicating voice, text data indicating text, and image data indicating images (e.g., still image data or video data). The data generation model 58 performs inference according to the instructions indicated by the prompt on the input inference data and outputs the inference results in one or more data formats such as voice data, text data, or image data. The data generation model 58 includes, for example, text generation AI, image generation AI, and multimodal generation AI. Here, inference refers to, for example, analysis, classification, prediction, and/or summarization. The specific processing unit 290 performs the specific processing described above using the data generation model 58. The data generation model 58 may be a fine-tuned model that outputs inference results from prompts without instructions, and in this case, the data generation model 58 can output inference results from prompts without instructions. The data processing device 12 and the like may include multiple types of data generation models 58, and the data generation model 58 may include AI other than generative AI. AI other than generative AI may include, for example, linear regression, logistic regression, decision trees, random forests, support vector machines (SVM), k-means clustering, convolutional neural networks (CNN), recurrent neural networks (RNN), generative adversarial networks (GAN), or naive Bayes, among others, and can perform various processing but are not limited to such examples. Additionally, AI may be an AI agent. Furthermore, when processing is performed by AI in each part described above, the processing may be performed partially or entirely by AI but is not limited to such examples. Additionally, processing implemented by AI including generative AI may be replaced with rule-based processing, and rule-based processing may be replaced with processing implemented by AI including generative AI.

Moreover, the processing by the data processing system 10 described above is executed by the specific processing unit 290 of the data processing device 12 or the control unit 46A of the smart device 14, but it may be executed by both the specific processing unit 290 of the data processing device 12 and the control unit 46A of the smart device 14. Additionally, the specific processing unit 290 of the data processing device 12 acquires or collects necessary information for processing from the smart device 14 or external devices, and the smart device 14 acquires or collects necessary information for processing from the data processing device 12 or external devices.

Each of the plurality of elements including the above-described acquisition unit, design unit, and verification unit is realized by at least one of, for example, the smart device 14 and the data processing apparatus 12. For example, the acquisition unit can acquire the latest policy from the Internet via the communication I/F 44 of the smart device 14. The design unit is realized, for example, by a specific processing unit 290 of the data processing apparatus 12, and performs design using AI based on the acquired policy. The verification unit is realized, for example, by the specific processing unit 290 of the data processing apparatus 12, and verifies, using AI, whether the generated design meets the standards. The correspondence between each unit and the device or control unit is not limited to the above examples, and various modifications are possible.

### Second Embodiment

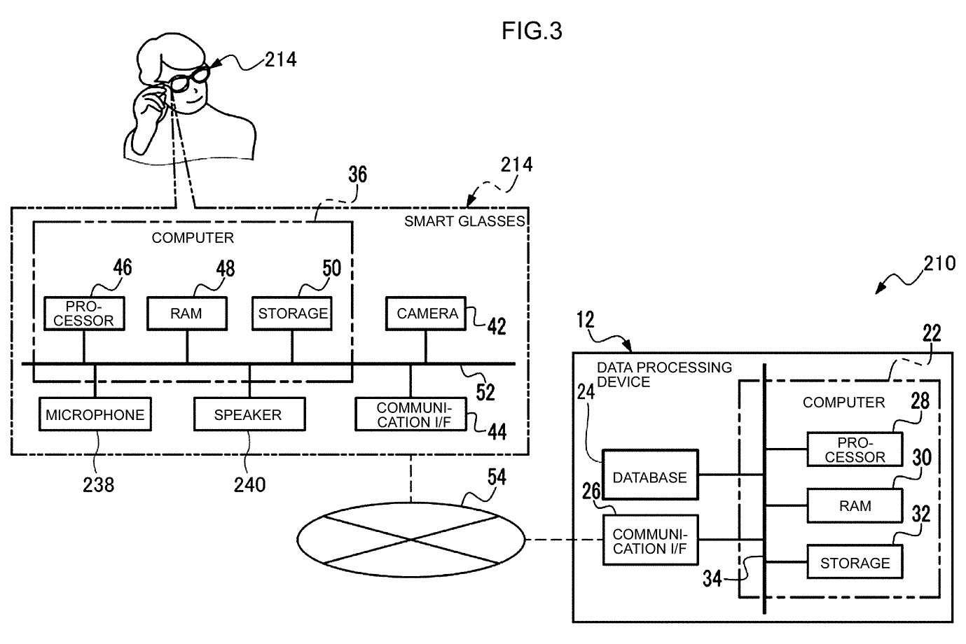

FIG. 3 shows an example configuration of a data processing system 210 according to the second embodiment.

As shown in FIG. 3, the data processing system 210 includes a data processing device 12 and smart glasses 214. An example of the data processing device 12 is a server.

The data processing device 12 includes a computer 22, a database 24, and a communication I/F 26. The computer 22 includes a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN and/or a LAN, among others.

The smart glasses 214 includes a computer 36, a microphone 238, a speaker 240, a camera 42, and a communication I/F 44. The computer 36 includes a processor 46, RAM 48, and storage 50. The processor 46, RAM 48, and storage 50 are connected to a bus 52. The microphone 238, speaker 240, and camera 42 are also connected to the bus 52.

The microphone 238 accepts voice from the user, accepting instructions, among others, from the user. The microphone 238 captures the voice emitted by the user, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors, and captures the surroundings of the user (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

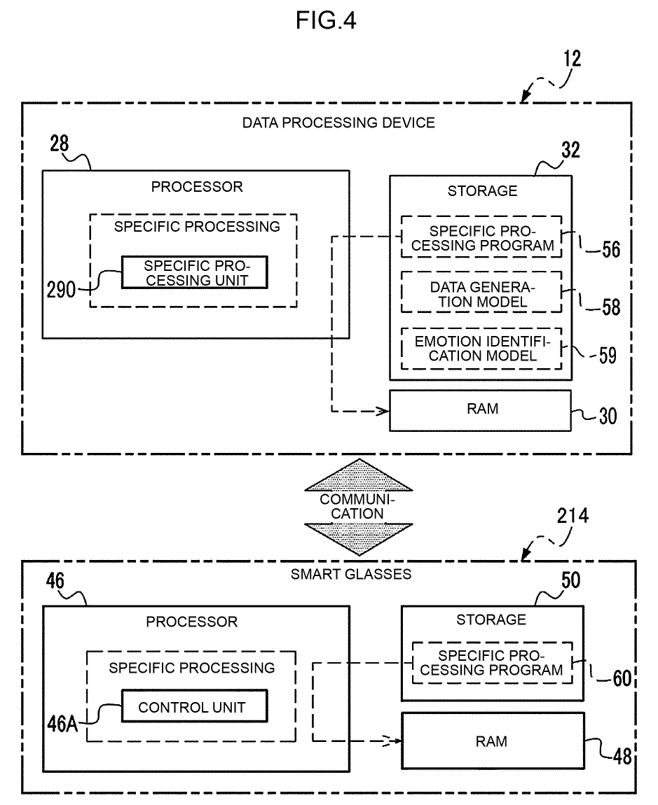

FIG. 4 shows an example of the main functions of the data processing device 12 and smart glasses 214. As shown in FIG. 4, specific processing is performed in the data processing device 12 by the processor 28. The storage 32 stores a specific processing program 56.

The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290. The specific processing unit 290 can estimate the user's emotions using the emotion identification model 59 and perform specific processing using the user's emotions. The emotion estimation function (emotion identification function) using the emotion identification model 59 includes estimating and predicting the user's emotions, but is not limited to such examples. Furthermore, emotion estimation and prediction may include, for example, emotion analysis.

In the smart glasses 214, specific processing is performed by the processor 46. The storage 50 stores a specific processing program 60. The processor 46 reads the specific processing program 60 from the storage 50 and executes it on the RAM 48. The specific processing is realized by the processor 46 operating as a control unit 46A according to the specific processing program 60 executed on the RAM 48. The smart glasses 214 may also have similar data generation models and emotion identification models as the data generation model 58 and emotion identification model 59, and perform the same processing as the specific processing unit 290 using these models.

Other devices besides the data processing device 12 may have the data generation model 58. For example, a server device may have the data generation model 58. In this case, the data processing device 12 communicates with the server device having the data generation model 58 to obtain processing results (e.g., prediction results) using the data generation model 58. The data processing device 12 may be a server device or a terminal device owned by the user (e.g., a mobile phone, robot, home appliance, etc.).

The specific processing unit 290 sends the results of specific processing to the smart glasses 214. In the smart glasses 214, the control unit 46A causes the speaker 240 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

The data generation model 58 is a so-called generative AI. An example of the data generation model 58 is a generative AI such as ChatGPT. The data generation model 58 is obtained by performing deep learning on a neural network. The data generation model 58 receives prompts containing instructions and inference data such as voice data indicating voice, text data indicating text, and image data indicating images (e.g., still image data or video data). The data generation model 58 performs inference according to the instructions indicated by the prompt on the input inference data and outputs the inference results in one or more data formats such as voice data, text data, or image data. The data generation model 58 includes, for example, text generation AI, image generation AI, and multimodal generation AI. Here, inference refers to, for example, analysis, classification, prediction, and/or summarization. The specific processing unit 290 performs the specific processing described above using the data generation model 58. The data generation model 58 may be a fine-tuned model that outputs inference results from prompts without instructions, and in this case, the data generation model 58 can output inference results from prompts without instructions. The data processing device 12 and the like may include multiple types of data generation models 58, and the data generation model 58 may include AI other than generative AI. AI other than generative AI may include, for example, linear regression, logistic regression, decision trees, random forests, support vector machines (SVM), k-means clustering, convolutional neural networks (CNN), recurrent neural networks (RNN), generative adversarial networks (GAN), or naive Bayes, among others, and can perform various processing but are not limited to such examples. Additionally, AI may be an AI agent. Furthermore, when processing is performed by AI in each part described above, the processing may be performed partially or entirely by AI but is not limited to such examples. Additionally, processing implemented by AI including generative AI may be replaced with rule-based processing, and rule-based processing may be replaced with processing implemented by AI including generative AI.

The data processing system 210 according to the second embodiment performs the same processing as the data processing system 10 according to the first embodiment. The processing by the data processing system 210 is executed by the specific processing unit 290 of the data processing device 12 or the control unit 46A of the smart glasses 214, but it may be executed by both the specific processing unit 290 of the data processing device 12 and the control unit 46A of the smart glasses 214. Additionally, the specific processing unit 290 of the data processing device 12 acquires or collects necessary information for processing from the smart glasses 214 or external devices, and the smart glasses 214 acquires or collects necessary information for processing from the data processing device 12 or external devices.

Each of the plurality of elements including the above-described acquisition unit, design unit, and verification unit is realized by at least one of, for example, the smart glasses 214 and the data processing apparatus 12. For example, the acquisition unit can acquire the latest policy from the Internet via the communication I/F 44 of the smart glasses 214. The design unit is realized, for example, by a specific processing unit 290 of the data processing apparatus 12, and performs design using AI based on the acquired policy. The verification unit is realized, for example, by the specific processing unit 290 of the data processing apparatus 12, and verifies, using AI, whether the generated design meets the standards. The correspondence between each unit and the device or control unit is not limited to the above examples, and various modifications are possible.

### Third Embodiment

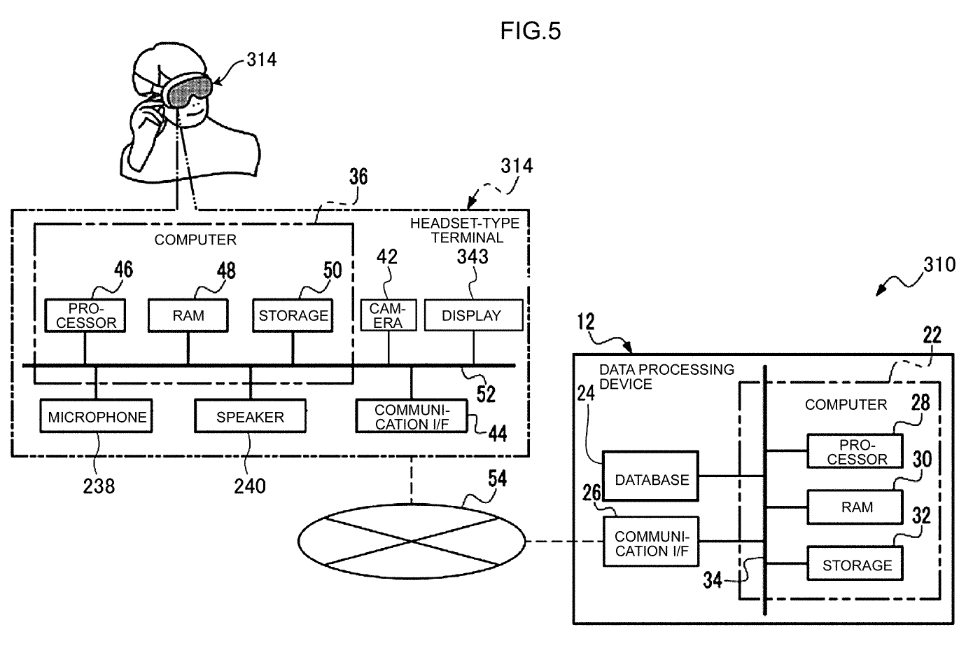

FIG. 5 shows an example configuration of a data processing system 310 according to the third embodiment.

As shown in FIG. 5, the data processing system 310 includes a data processing device 12 and a headset-type terminal 314. An example of the data processing device 12 is a server.

The data processing device 12 includes a computer 22, a database 24, and a communication I/F 26. The computer 22 includes a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN and/or a LAN, among others.

The headset-type terminal 314 includes a computer 36, a microphone 238, a speaker 240, a camera 42, a communication I/F 44, and a display 343. The computer 36 includes a processor 46, RAM 48, and storage 50. The processor 46, RAM 48, and storage 50 are connected to a bus 52. The microphone 238, speaker 240, camera 42, and display 343 are also connected to the bus 52.

The microphone 238 accepts voice from the user, accepting instructions, among others, from the user. The microphone 238 captures the voice emitted by the user, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors, and captures the surroundings of the user (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

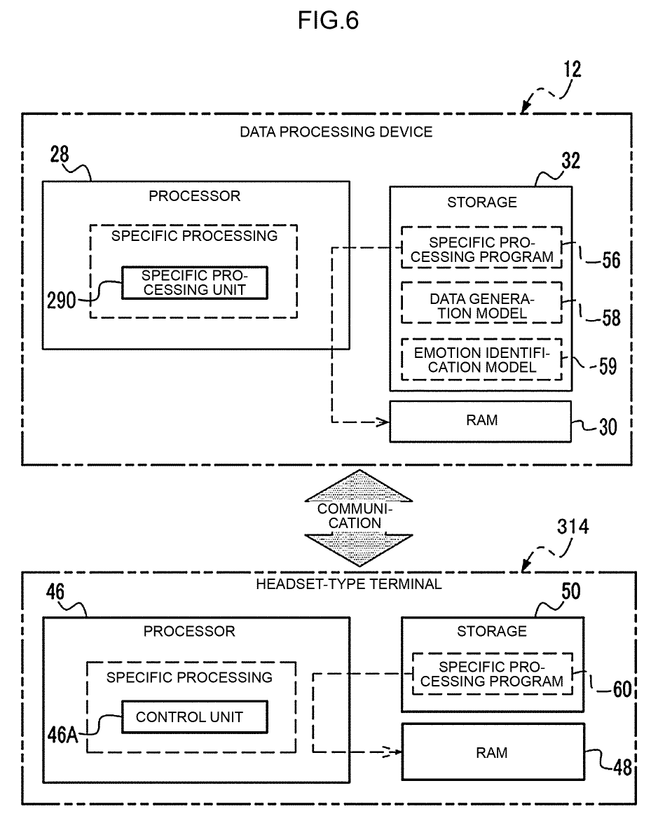

FIG. 6 shows an example of the main functions of the data processing device 12 and the headset-type terminal 314. As shown in FIG. 6, specific processing is performed in the data processing device 12 by the processor 28. The storage 32 stores a specific processing program 56.

The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290. The specific processing unit 290 can estimate the user's emotions using the emotion identification model 59 and perform specific processing using the user's emotions. The emotion estimation function (emotion identification function) using the emotion identification model 59 includes estimating and predicting the user's emotions, but is not limited to such examples. Furthermore, emotion estimation and prediction may include, for example, emotion analysis.

In the headset-type terminal 314, specific processing is performed by the processor 46. The storage 50 stores a specific program 60. The processor 46 reads the specific program 60 from the storage 50 and executes it on the RAM 48. The specific processing is realized by the processor 46 operating as a control unit 46A according to the specific program 60 executed on the RAM 48. The headset-type terminal 314 may also have similar data generation models and emotion identification models as the data generation model 58 and emotion identification model 59, and perform the same processing as the specific processing unit 290 using these models.

Other devices besides the data processing device 12 may have the data generation model 58. For example, a server device may have the data generation model 58. In this case, the data processing device 12 communicates with the server device having the data generation model 58 to obtain processing results (e.g., prediction results) using the data generation model 58. The data processing device 12 may be a server device or a terminal device owned by the user (e.g., a mobile phone, robot, home appliance, etc.).

The specific processing unit 290 sends the results of specific processing to the headset-type terminal 314. In the headset-type terminal 314, the control unit 46A causes the speaker 240 and the display 343 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

The data generation model 58 is a so-called generative AI. An example of the data generation model 58 is a generative AI such as ChatGPT. The data generation model 58 is obtained by performing deep learning on a neural network. The data generation model 58 receives prompts containing instructions and inference data such as voice data indicating voice, text data indicating text, and image data indicating images (e.g., still image data or video data). The data generation model 58 performs inference according to the instructions indicated by the prompt on the input inference data and outputs the inference results in one or more data formats such as voice data, text data, or image data. The data generation model 58 includes, for example, text generation AI, image generation AI, and multimodal generation AI. Here, inference refers to, for example, analysis, classification, prediction, and/or summarization. The specific processing unit 290 performs the specific processing described above using the data generation model 58. The data generation model 58 may be a fine-tuned model that outputs inference results from prompts without instructions, and in this case, the data generation model 58 can output inference results from prompts without instructions. The data processing device 12 and the like may include multiple types of data generation models 58, and the data generation model 58 may include AI other than generative AI. AI other than generative AI may include, for example, linear regression, logistic regression, decision trees, random forests, support vector machines (SVM), k-means clustering, convolutional neural networks (CNN), recurrent neural networks (RNN), generative adversarial networks (GAN), or naive Bayes, among others, and can perform various processing but are not limited to such examples. Additionally, AI may be an AI agent. Furthermore, when processing is performed by AI in each part described above, the processing may be performed partially or entirely by AI but is not limited to such examples. Additionally, processing implemented by AI including generative AI may be replaced with rule-based processing, and rule-based processing may be replaced with processing implemented by AI including generative AI.

The data processing system 310 according to the third embodiment performs the same processing as the data processing system 10 according to the first embodiment. The processing by the data processing system 310 is executed by the specific processing unit 290 of the data processing device 12 or the control unit 46A of the headset-type terminal 314, but it may be executed by both the specific processing unit 290 of the data processing device 12 and the control unit 46A of the headset-type terminal 314. Additionally, the specific processing unit 290 of the data processing device 12 acquires or collects necessary information for processing from the headset-type terminal 314 or external devices, and the headset-type terminal 314 acquires or collects necessary information for processing from the data processing device 12 or external devices.

Each of the plurality of elements including the above-described acquisition unit, design unit, and verification unit is realized by at least one of, for example, the headset-type terminal 314 and the data processing apparatus 12. For example, the acquisition unit can acquire the latest policy from the Internet via the communication I/F 44 of the headset-type terminal 314. The design unit is realized, for example, by a specific processing unit 290 of the data processing apparatus 12, and performs design using AI based on the acquired policy. The verification unit is realized, for example, by the specific processing unit 290 of the data processing apparatus 12, and verifies, using AI, whether the generated design meets the standards. The correspondence between each unit and the device or control unit is not limited to the above examples, and various modifications are possible.

### Fourth Embodiment

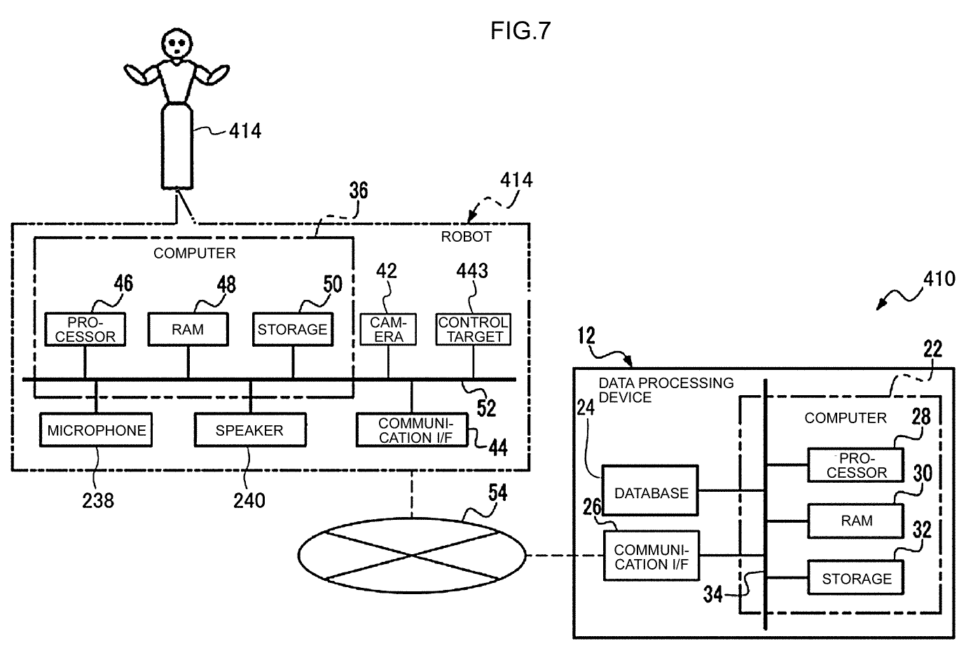

FIG. 7 shows an example configuration of a data processing system 410 according to the fourth embodiment.

As shown in FIG. 7, the data processing system 410 includes a data processing device 12 and a robot 414. An example of the data processing device 12 is a server.

The data processing device 12 includes a computer 22, a database 24, and a communication I/F 26. The computer 22 includes a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN and/or a LAN, among others.

The robot 414 includes a computer 36, a microphone 238, a speaker 240, a camera 42, a communication I/F 44, and a control target 443. The computer 36 includes a processor 46, RAM 48, and storage 50. The processor 46, RAM 48, and storage 50 are connected to a bus 52. The microphone 238, speaker 240, camera 42, and control target 443 are also connected to the bus 52.

The microphone 238 accepts voice from the user, accepting instructions, among others, from the user. The microphone 238 captures the voice emitted by the user, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS image sensors or CCD image sensors, and captures the surroundings of the user (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

The control target 443 includes a display device, LEDs for the eyes, and motors for driving arms, hands, and feet, among others. The posture and gestures of the robot 414 are controlled by controlling the motors for the arms, hands, and feet, among others. Some emotions of the robot 414 can be expressed by controlling these motors. Additionally, the expression of the robot 414 can be expressed by controlling the lighting state of the LEDs for the eyes of the robot 414.

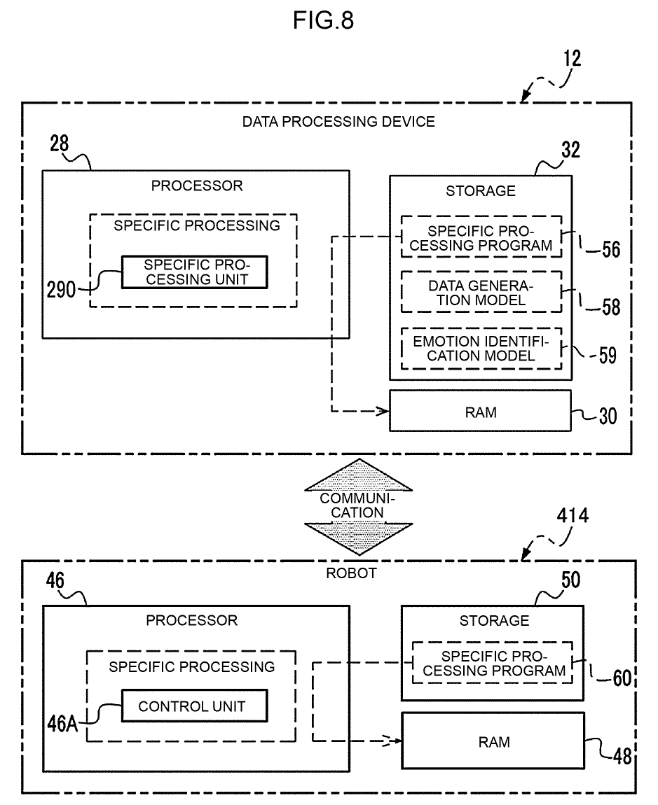

FIG. 8 shows an example of the main functions of the data processing device 12 and the robot 414. As shown in FIG. 8, specific processing is performed in the data processing device 12 by the processor 28. The storage 32 stores a specific processing program 56.

The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290. The specific processing unit 290 can estimate the user's emotions using the emotion identification model 59 and perform specific processing using the user's emotions. The emotion estimation function (emotion identification function) using the emotion identification model 59 includes estimating and predicting the user's emotions, but is not limited to such examples. Furthermore, emotion estimation and prediction may include, for example, emotion analysis.

In the robot 414, specific processing is performed by the processor 46. The storage 50 stores a specific program 60. The processor 46 reads the specific program 60 from the storage 50 and executes it on the RAM 48. The specific processing is realized by the processor 46 operating as a control unit 46A according to the specific program 60 executed on the RAM 48. The robot 414 may also have similar data generation models and emotion identification models as the data generation model 58 and emotion identification model 59, and perform the same processing as the specific processing unit 290 using these models.

Other devices besides the data processing device 12 may have the data generation model 58. For example, a server device may have the data generation model 58. In this case, the data processing device 12 communicates with the server device having the data generation model 58 to obtain processing results (e.g., prediction results) using the data generation model 58. The data processing device 12 may be a server device or a terminal device owned by the user (e.g., a mobile phone, robot, home appliance, etc.).

The specific processing unit 290 sends the results of specific processing to the robot 414. In the robot 414, the control unit 46A causes the speaker 240 and the control target 443 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

The data generation model 58 is a so-called generative AI. An example of the data generation model 58 is a generative AI such as ChatGPT. The data generation model 58 is obtained by performing deep learning on a neural network. The data generation model 58 receives prompts containing instructions and inference data such as voice data indicating voice, text data indicating text, and image data indicating images (e.g., still image data or video data). The data generation model 58 performs inference according to the instructions indicated by the prompt on the input inference data and outputs the inference results in one or more data formats such as voice data, text data, or image data. The data generation model 58 includes, for example, text generation AI, image generation AI, and multimodal generation AI. Here, inference refers to, for example, analysis, classification, prediction, and/or summarization. The specific processing unit 290 performs the specific processing described above using the data generation model 58. The data generation model 58 may be a fine-tuned model that outputs inference results from prompts without instructions, and in this case, the data generation model 58 can output inference results from prompts without instructions. The data processing device 12 and the like may include multiple types of data generation models 58, and the data generation model 58 may include AI other than generative AI. AI other than generative AI may include, for example, linear regression, logistic regression, decision trees, random forests, support vector machines (SVM), k-means clustering, convolutional neural networks (CNN), recurrent neural networks (RNN), generative adversarial networks (GAN), or naive Bayes, among others, and can perform various processing but are not limited to such examples. Additionally, AI may be an AI agent. Furthermore, when processing is performed by AI in each part described above, the processing may be performed partially or entirely by AI but is not limited to such examples. Additionally, processing implemented by AI including generative AI may be replaced with rule-based processing, and rule-based processing may be replaced with processing implemented by AI including generative AI.

The data processing system 410 according to the fourth embodiment performs the same processing as the data processing system 10 according to the first embodiment. The processing by the data processing system 410 is executed by the specific processing unit 290 of the data processing device 12 or the control unit 46A of the robot 414, but it may be executed by both the specific processing unit 290 of the data processing device 12 and the control unit 46A of the robot 414. Additionally, the specific processing unit 290 of the data processing device 12 acquires or collects necessary information for processing from the robot 414 or external devices, and the robot 414 acquires or collects necessary information for processing from the data processing device 12 or external devices.

Each of the plurality of elements including the above-described acquisition unit, design unit, and verification unit is realized by at least one of, for example, the robot 414 and the data processing apparatus 12. For example, the acquisition unit can acquire the latest policy from the Internet via the communication I/F 44 of the robot 414. The design unit is realized, for example, by a specific processing unit 290 of the data processing apparatus 12, and performs design using AI based on the acquired policy. The verification unit is realized, for example, by the specific processing unit 290 of the data processing apparatus 12, and verifies, using AI, whether the generated design meets the standards. The correspondence between each unit and the device or control unit is not limited to the above examples, and various modifications are possible.

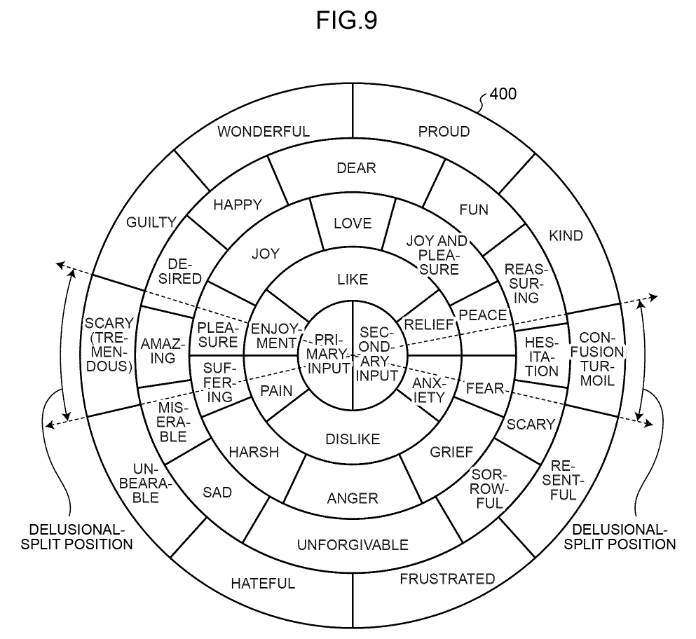

Note that the emotion identification model 59 as an emotion engine may determine the user's emotions according to a specific mapping. Specifically, the emotion identification model 59 may determine the user's emotions according to an emotion map, which is a specific mapping (see FIG. 9). Similarly, the emotion identification model 59 may determine the robot's emotions, and the specific processing unit 290 may perform specific processing using the robot's emotions.

FIG. 9 is a diagram showing an emotion map 400 where multiple emotions are mapped. In the emotion map 400, emotions are arranged concentrically radiating from the center. The closer to the center of the concentric circles, the more primitive the state of emotions is arranged. On the outer side of the concentric circles, emotions representing states and behaviors arising from mood are arranged. Emotions encompass concepts including emotional and mental states. On the left side of the concentric circles, emotions generally generated from reactions occurring in the brain are arranged. On the right side of the concentric circles, emotions generally induced by situational judgment are arranged. On the top and bottom of the concentric circles, emotions generated from reactions occurring in the brain and induced by situational judgment are arranged. Additionally, on the upper side of the concentric circles, "pleasant" emotions are arranged, and on the lower side, "unpleasant" emotions are arranged. In this way, in the emotion map 400, multiple emotions are mapped based on the structure from which emotions arise, and emotions that tend to occur simultaneously are mapped nearby.

These emotions are distributed in the 3 o'clock direction of the emotion map 400, and they usually move back and forth around reassurance and anxiety. In the right half of the emotion map 400, situational recognition takes precedence over internal sensations, giving a calm impression.

The inner side of the emotion map 400 represents the mind, and the outer side represents behavior, so the further out on the emotion map 400, the more visible (expressed in behavior) emotions become.

Here, human emotions are based on various balances like posture and blood sugar levels, and when these balances move away from the ideal, they indicate discomfort, and when they approach the ideal, they indicate comfort. In robots, cars, motorcycles, etc., emotions can be created based on various balances like posture and battery level, indicating discomfort when these balances move away from the ideal and comfort when they approach the ideal. The emotion map may be generated based on Dr. Mitsuyoshi's emotion map (Research on speech emotion recognition and brain physiological signal analysis systems related to emotions, Tokushima University, Doctoral dissertation: https://ci.nii.ac.jp/naid/500000375379). In the left half of the emotion map, emotions belonging to the domain called "reactions," where sensations take precedence, are aligned. Additionally, in the right half of the emotion map, emotions belonging to the domain called "situations," where situational recognition takes precedence, are aligned.

In the emotion map, two emotions that promote learning are defined. One is a negative emotion around "repentance" or "reflection" on the situation side. In other words, when a negative emotion arises in the robot, like "I never want to feel this way again" or "I don't want to be scolded again." The other is an emotion around "desire" on the reaction side, which is positive. In other words, it is a positive feeling like "I want more" or "I want to know more."

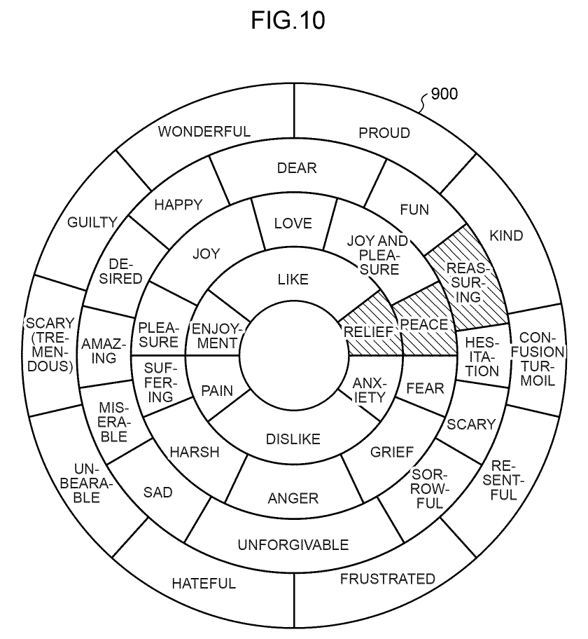

The emotion identification model 59 inputs user input into a pre-learned neural network, acquires emotion values indicating each emotion shown in the emotion map 400, and determines the user's emotions. This neural network is pre-learned based on multiple training data consisting of user input and combinations of emotion values indicating each emotion shown in the emotion map 400. Additionally, this neural network is learned so that emotions placed near each other in the emotion map 900 shown in FIG. 10 have similar values. FIG. 10 shows an example where multiple emotions like "reassured," "calm," and "confident" have similar emotion values.

In the above embodiments, an example form where specific processing is performed by a single computer 22 was described, but the technology disclosed herein is not limited to this, and distributed processing for specific processing by multiple computers including the computer 22 may be performed.

In the above embodiments, an example form where the specific processing program 56 is stored in the storage 32 was described, but the technology disclosed herein is not limited to this. For example, the specific processing program 56 may be stored in portable non-transitory storage media readable by a computer, such as a USB (Universal Serial Bus) memory. The specific processing program 56 stored in non-transitory storage media is installed in the computer 22 of the data processing device 12. The processor 28 executes specific processing according to the specific processing program 56.

Additionally, the specific processing program 56 may be stored in a storage device, such as a server connected to the data processing device 12 via the network 54, and downloaded and installed on the computer 22 in response to requests from the data processing device 12.

Furthermore, it is not necessary to store all of the specific processing program 56 in storage devices such as servers connected to the data processing device 12 via the network 54 or all in the storage 32, and a part of the specific processing program 56 may be stored.

Various processors, as shown next, can be used as hardware resources for executing specific processing. As processors, general-purpose processors that function as hardware resources for executing specific processing by executing software, i.e., programs, such as a CPU, can be mentioned. Additionally, as processors, dedicated electrical circuits with circuit configurations specially designed to execute specific processing, such as FPGA (Field-Programmable Gate Array), PLD (Programmable Logic Device), or ASIC (Application Specific Integrated Circuit), can be mentioned. Each processor has a built-in or connected memory, and each processor executes specific processing using the memory.

Hardware resources for executing specific processing may be composed of one of these various processors or a combination of two or more processors of the same or different types (e.g., a combination of multiple FPGAs or a combination of a CPU and FPGA). Additionally, hardware resources for executing specific processing may be a single processor.

As an example of composing with a single processor, firstly, there is a form where one or more CPUs and software are combined to constitute a single processor, which functions as hardware resources for executing specific processing. Secondly, there is a form using a processor, such as SoC (System-on-a-chip), that realizes the function of an entire system including multiple hardware resources for executing specific processing with a single IC chip. In this way, specific processing is realized using one or more of the various processors as hardware resources.

Furthermore, as a hardware structure of these various processors, more specifically, electrical circuits combined with circuit elements such as semiconductor elements can be used. Additionally, the specific processing described above is merely one example. Therefore, it goes without saying that unnecessary steps may be deleted, new steps may be added, or the order of processing may be changed within the scope not departing from the gist.

Additionally, in the examples described above, the explanation was divided into the first embodiment to the fourth embodiment, but parts or all of these embodiments may be combined. Additionally, the smart device 14, smart glasses 214, headset-type terminal 314, and robot 414 are examples, and each may be combined, or other devices may be used. Additionally, the examples described above were explained by dividing into form example 1 and form example 2, but these may be combined.

The descriptions and drawings shown above are detailed explanations of parts related to the technology disclosed herein and are merely examples of the technology disclosed herein. For example, the explanations regarding configurations, functions, actions, and effects above are explanations regarding examples of configurations, functions, actions, and effects of parts related to the technology disclosed herein. Therefore, it goes without saying that within the scope not departing from the gist of the technology disclosed herein, unnecessary parts may be deleted, new elements may be added, or replacements may be made to the descriptions and drawings shown above. Additionally, to avoid complexity and facilitate understanding of parts related to the technology disclosed herein, explanations concerning technical common knowledge and the like that do not require special explanation for enabling the implementation of the technology disclosed herein are omitted in the descriptions and drawings shown above.

All documents, patent applications, and technical standards described in this specification are incorporated by reference to the same extent as if each document, patent application, and technical standard were specifically and individually stated to be incorporated by reference in this specification.

[Additional Note 1] A system including: an acquisition unit configured to acquire the latest policy; a design unit configured to automatically perform design based on the policy acquired by the acquisition unit; and a verification unit configured to verify the design generated by the design unit.

[Additional Note 2] The system according to Additional Note 1, wherein the acquisition unit is configured to periodically acquire the latest policies such as the Building Standards Act and disaster prevention standards.

[Additional Note 3] The system according to Additional Note 1, wherein the design unit is configured to perform design taking into account earthquake resistance and fire resistance based on the acquired policy.

[Additional Note 4] The system according to Additional Note 1, wherein the design unit is configured to design evacuation routes and the arrangement of emergency equipment based on disaster prevention standards.

[Additional Note 5] The system according to Additional Note 1, wherein the verification unit is configured to verify whether the generated design meets the standards.

[Additional Note 6] The system according to Additional Note 1, wherein the acquisition unit is configured to estimate the user's emotion and adjust the timing of policy acquisition based on the estimated user's emotion.

[Additional Note 7] The system according to Additional Note 1, wherein the acquisition unit is configured to analyze the history of past policy changes at the time of policy acquisition and select an optimal acquisition method.

[Additional Note 8] The system according to Additional Note 1, wherein the acquisition unit is configured to perform filtering at the time of policy acquisition in consideration of region-specific building standards and disaster prevention standards.

[Additional Note 9] The system according to Additional Note 1, wherein the acquisition unit is configured to estimate the user's emotion and determine the priority of policies to be acquired based on the estimated user's emotion.

[Additional Note 10] The system according to Additional Note 1, wherein the acquisition unit is configured to preferentially acquire highly relevant policies at the time of policy acquisition in consideration of the user's geographic location information.

[Additional Note 11] The system according to Additional Note 1, wherein the acquisition unit is configured to analyze the user's social media activity at the time of policy acquisition and acquire relevant policies.

[Additional Note 12] The system according to Additional Note 1, wherein the design unit is configured to estimate the user's emotion and adjust the method of expressing the design based on the estimated user's emotion.

[Additional Note 13] The system according to Additional Note 1, wherein the design unit is configured to adjust the level of detail of the design based on the importance of the policy at the time of design.

[Additional Note 14] The system according to Additional Note 1, wherein the design unit is configured to apply different design algorithms according to the intended use of the building at the time of design.

[Additional Note 15] The system according to Additional Note 1, wherein the design unit is configured to estimate the user's emotion and adjust the length of the design based on the estimated user's emotion.

[Additional Note 16] The system according to Additional Note 1, wherein the design unit is configured to determine the priority of the design based on the timing of policy updates at the time of design.

[Additional Note 17] The system according to Additional Note 1, wherein the design unit is configured to adjust the order of design based on the relevance of the buildings at the time of design.

[Additional Note 18] The system according to Additional Note 1, wherein the verification unit is configured to estimate the user's emotion and adjust the verification criteria based on the estimated user's emotion.

[Additional Note 19] The system according to Additional Note 1, wherein the verification unit is configured to improve the accuracy of verification by considering the interrelationships of the designs at the time of verification.

[Additional Note 20] The system according to Additional Note 1, wherein the verification unit is configured to perform verification in consideration of the attribute information of the designer at the time of verification.

[Additional Note 21] The system according to Additional Note 1, wherein the verification unit is configured to estimate the user's emotion and adjust the order in which the results of verification are displayed based on the estimated user's emotion.

[Additional Note 22] The system according to Additional Note 1, wherein the verification unit is configured to perform verification in consideration of the geographical distribution of the designs at the time of verification.

[Additional Note 23] The system according to Additional Note 1, wherein the verification unit is configured to improve the accuracy of verification by referring to related literature of the designs at the time of verification.

What is claimed is:

1. A system comprising: an acquisition unit configured to acquire the latest policy; a design unit configured to automatically perform design based on the policy acquired by the acquisition unit; and a verification unit configured to verify the design generated by the design unit.

2. The system according to claim 1, wherein the acquisition unit is configured to periodically acquire the latest policies such as the Building Standards Act and disaster prevention standards.

3. The system according to claim 1, wherein the design unit is configured to perform design taking into account earthquake resistance and fire resistance based on the acquired policy.

4. The system according to claim 1, wherein the design unit is configured to design evacuation routes and the arrangement of emergency equipment based on disaster prevention standards.

5. The system according to claim 1, wherein the verification unit is configured to verify whether the generated design meets the standards.

6. The system according to claim 1, wherein the acquisition unit is configured to estimate the user's emotion and adjust the timing of policy acquisition based on the estimated user's emotion.

7. The system according to claim 1, wherein the acquisition unit is configured to analyze the history of past policy changes at the time of policy acquisition and select an optimal acquisition method.

8. The system according to claim 1, wherein the acquisition unit is configured to perform filtering at the time of policy acquisition in consideration of region-specific building standards and disaster prevention standards.

9. The system according to claim 1, wherein the acquisition unit is configured to estimate the user's emotion and determine the priority of policies to be acquired based on the estimated user's emotion.

10. The system according to claim 1, wherein the acquisition unit is configured to preferentially acquire highly relevant policies at the time of policy acquisition in consideration of the user's geographic location information.
